(19) United States
(12) Patent Application Publication
(10) Pub. No.: US 2006/0165143 A1
(43) Pub. Date: Jul. 27, 2006

(54) Nitride semiconductor laser device and manufacturing method thereof

(75) Inventor: Hiroshi Ohno, Takatsuki-shi (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/336,841

(22) Filed: Jan. 23, 2006

(30) Foreign Application Priority Data
Jan. 24, 2005 (JP) 2005-016177

(51) Int. Cl. H01S 5/00

(52) U.S. Cl. 372/46.015; 372/46.016

(57) ABSTRACT

In the fields of semiconductor laser devices made of nitride semiconductor layers, the present invention provides a semiconductor laser device having higher output and longer lifetime characteristics and a manufacturing method thereof. The semiconductor laser device according to the present invention includes a resonator that has: the first cladding layer which is made of n-type GaN or n-type AlGaN; an active layer which is made of an AlGaInN multiple quantum well and positioned above the first cladding layer; the second cladding layer which is made of p-type or undoped GaN, or p-type or undoped AlGaN and positioned above the active layer; and the third cladding layer which is made of p-type GaN or p-type AlGaN and positioned above the second cladding layer. The resonator also has an ion implanted part at an end part of the resonator.

### BACKGROUND OF THE INVENTION

1. Field of the Invention

The present invention relates to a nitride semiconductor laser device which emits blue to ultraviolet light and a manufacturing method thereof, and more specifically to a nitride semiconductor laser device which has advantages of a high output operation and a long time operation and a manufacturing method thereof.

2. Description of the Related Art

Conventionally, as a reading/writing device for CDs, DVDs, and laser devices for communication, a III-V compound semiconductor laser devices, such as an aluminium-gallium-arsenide (AlGaAs) infrared laser device and an indium-gallium-phosphide (InGaP) red laser device, have been widely used. In recent years, a laser device emitting a short wavelength light, such as blue or ultraviolet light, has been made of a nitride semiconductor represented by AlₓGa_{y}In_{(1-x-y)}N (where 0≦x≦1, 0≦y≦1, 0≦1-x-y≦1), and utilized as a light source for writing and reading a high-density optical disk, such as a next generation DVD (Blu-ray Disc). Currently, a blue laser device having an output of tens of milliwatt (mW) is on the market. However, the blue laser device is required to have higher outputting in order to improve a recording speed in the future.

The blue laser device which has been utilized is described with reference to FIG. 1. FIG. 1 is a cross-sectional view showing a structure of a blue laser device which is disclosed in “High-Power, Long-Lifetime InGaN/GaN/AlGaN-based Laser Diodes Grown on Pure GaN Substrates”, Shuji Nakamura et al., Japanese Journal of Applied Physics, Vol. 37, pp. 309-312 (1998). A substrate 901 is made of gallium nitride (GaN) having a thickness of 100 μm which is grown on a sapphire substrate by metal organic chemical vapor deposition (MOCVD) using an epitaxially lateral over growth technology (ELOG). On the substrate 901 are stacked: an n-type GaN layer 902; an n-type cladding layer 903 which has an n-In_{0.1}Ga_{0.9}N layer having a thickness of 0.1 μm, a modulation doped superlattice layer made of 240 Al_{0.14}Ga_{0.86}N(25Å)/n-GaN(25Å), and an n-GaN layer having a thickness of 0.1 μm; an active layer 904 which has a multiple quantum well (MQW) made of In_{0.02}Ga_{0.98}N/In_{0.15}Ga_{0.85}N; a p-type cladding layer 905 which has a p-GaN layer having a thickness of 0.1 μm and a modulation doped superlattice layer made of 120 Al_{0.14}Ga_{0.86}N(25 Å)/p-GaN(25Å); a p-electrode 906; an n-electrode 907; and a dielectric insulating film 908 which is made of silicon dioxide (SiO₂). In the nitride semiconductor laser device, the p-type cladding layer 905 has a ridge-shaped waveguide structure, and the SiO₂ dielectric insulating film 908 is formed to have a striped shape, so that current stricture and light confinement can be achieved to cause laser oscillation. It is disclosed that the nitride semiconductor laser device has a lifetime of about 10,000 hours with an output of 5 mW in a case of a threshold current of 70 mA.

It has been known that, in order to realize the high-output laser device, for an infrared laser device and a red laser device, restraint on deterioration of an end surface of an resonator (hereinafter, referring to as a resonator end surface, where the resonator is viewed along a resonance direction) is quite important. The transformation is called catastrophic optical damage (COD). The COD causes positive feedback in which heating resulted from a surface energy level or increase of non-irradiative recombination increases crystalline defects on a region positioned closely to the resonator end surface (hereinafter, referring to as a resonator end part), and the increased crystalline defects cause further non-irradiative recombination, which eventually accelerates the crystalline defects. As a result, a temperature on the resonator end surface rises abnormally, thereby damaging the resonator end surface, so that the laser device is damaged. Therefore, to realize a high-output operation, it is desired not to damage the resonator end surface even when the light is emitted with high output. Until now, as a structure for realizing COD restraints and the high-output operation of the laser device, a window structure for restraining the heating on the resonator end surface has been realized, using impurity diffusion, ion implantation, and the like, by disordering an active layer at the resonator end part to become a part in which emitted light is not absorbed or by increasing resistance of the active layer thereby currents are not injected to the part.

The conventional infrared laser device which has the window-structure formed by ion implantation is described with reference to FIG. 2. FIG. 2 shows a structure of a window-structure infrared laser device which is described in Japanese Patent Publication No. 6-48742. The laser device has: an n-electrode 1001; an n-type GaAs substrate 1002; an n-type AlGaAs cladding layer 1003; an active layer 1005 which has an AlAs/GaAs superlattice; a p-type AlGaAs cladding layer 1006; a current blocking layer 1007 which is made of n-type GaAs; and a p-electrode 1008. Alternatively, the infrared laser device further has a disordered part 1004 which is formed by disordering the active layer 1005 by applying ion implantation at the resonator end part. The disordered part 1004 may be formed by disordering the active layer using impurity diffusion. With the above structure, a bandgap at the disordered part 1004 of the resonator end part becomes greater than a bandgap of the active layer 1005, the disordered part 1004 does not absorb light emitted from the active layer 1005, and light is not absorbed in the resonator end part, so that it is possible to restrain the heating on the resonator end part. As a result, the COD and the resonator end surface deterioration can be restrained, so that it is possible to realize a reliable laser device having high output and long lifetime. Regarding the laser device structure having such window structure, various structures have been proposed for red laser devices or infrared laser devices. One example of those structures is disclosed in Japanese Patent Laid-Open No. 11-26866.

### SUMMARY OF THE INVENTION

However, a window structure for a nitride semiconductor laser device has hardly been proposed. Moreover, technologies such as impurity diffusion and ion implantation are not established to utilized for the nitride semiconductor, so that effects for forming such a window structure, such as the disordering effect and the higher resistance effect for a quantum well structure, are hardly identified. In general, the nitride semiconductor is thermally-stable more than other compound semiconductors, so that the process such as impurity diffusion has hardly been utilized for the nitride semiconductor.

In the case of the nitride semiconductor, a p-type layer is generally doped with magnesium (Mg). Such layer is known to have a function as a p-type layer only when a p-type impurity Mg is activated by heat treatment of 750° C. to 800° C. after crystal growth. If the activation temperature is too low, obtained hole concentration is not enough. On the other hand, if the activation temperature is too high, nitrogen is desorbed from the surface. Therefore, if nitrogen is desorbed from the surface, the nitrogen vacancy serve as a donor, so that the layer cannot have the function as a p-type layer although this does not cause a problem for the n-type layer.

Disordering of the quantum well structure requires heat treatment at a high temperature. An AlGaAs laser device requires heat treatment of only 500° C. to 700° C. after ion implantation or for impurity diffusion. However, the nitride semiconductor requires heat treatment of 800° C. to 1300° C., since the nitride semiconductor is more thermally-stable. The heat treatment of such a high temperature causes a problem of the nitrogen desorption from a surface of the p-type layer as described above, thereby resulting in deterioration of the laser device characteristics. Since a pn-junction is indispensable for semiconductor laser devices, the p-type layer deterioration is a serious problem for the laser device characteristics.

Thus, in order to address the above problems, an object of the present invention is to provide a nitride semiconductor laser device which emits blue or ultraviolet light and has high output and long lifetime, and a manufacturing method thereof.

In order to solve the above problems and to achieve the above object, the nitride semiconductor laser device according to the present invention is made of a nitride semiconductor, the nitride semiconductor laser device including a resonator which causes laser oscillation, wherein the resonator has an transformed part at an end part of the resonator in a resonance direction.

Thus, the nitride semiconductor laser device according to the present invention has a transformed part which is formed by applying ion implantation at the resonator end part. Thereby it is possible to realize a nitride semiconductor laser device having high output and long lifetime.

Here, the resonator may have: an n-type cladding layer; an active layer positioned above the n-type cladding layer; and a p-type cladding layer positioned above the active layer, and the transformed part is positioned in the p-type cladding layer. Furthermore, the transformed part may be a part in the p-type cladding layer, the part having resistance that is increased more than other part in the p-type cladding layer.

With the above structure, a region which is not injected with current (hereinafter, refers to a current non-injected region) is formed at the resonator end part, so that it is possible to restraint the deterioration of the resonator end surface during a high-output operation.

Here, the nitride semiconductor laser device may has a ridge-stripe-shaped waveguide.

With the above structure, it is possible to realize a nitride semiconductor laser device having a ridge-stripe-shaped waveguide.

Here, the resonator may have a current blocking layer which is positioned above the active layer and which has a stripe-shaped opening, and the transformed part is in the opening.

With the above structure, it is possible to realize a nitride semiconductor laser device having an embedded-stripe-shaped waveguide.

Here, the resonator may have: an n-type cladding layer; an active layer positioned above the n-type cladding layer; and a p-type cladding layer positioned above the active layer, and the transformed part is positioned in the active layer. Furthermore, the transformed part may be a part in the active layer, the part being disordered.

With the above structure, light is not absorbed at a part of the active layer, so that it is possible to restrain the deterioration of the resonator end surface during a high-output operation.

Here, the transformed part may be a part in the active layer, the part having bandgap energy that is increased more than bandgap energy of other part in the active layer. Furthermore, the active layer may have a barrier layer made of Al_{xb}Ga_{yb}In_{(1-xb-yb)}N (where 0≦xb≦1, 0≦yb≦1, 0≦1xb-yb≦1) and a well layer made of Al_{xw}Ga_{yw}In_{(1-xw-yw)}N (where 0≦xw≦1, 0≦yw 1, 0≦1-xw-yw≦1), and a bandgap of AlₓₐGa_{ya}In_{(1-xa-ya)}N (where 0≦xa≦1, 0≦ya≦1, 0≦1-xa-ya≦1) which is represented by an average composition of material of the active layer may be greater than a bandgap of the barrier layer or the well layer.

With the above structure, it is possible to restrain light absorption in the active layer which is formed as the transformed part.

Here, the transformed part may be a part where at least one ion specie of hydrogen (H), boron (B), carbon (C), nitrogen (N), aluminium (Al), silicon (Si), zinc (Zn), gallium (Ga), arsenic (As), and Indium (In) is implanted.

With the above structure, hydrogen (H), boron (B), carbon (C), nitrogen (N), and zinc (Zn) have an effect of increasing resistance, silicon (Si) has an effect of forming the implanted part to be n-type, and aluminium (Al), gallium (Ga), arsenic (As), and Indium (In) have an effect of disordering the implanted part.

Here, the active layer may be made of aluminum-gallium-indium-nitride (AlGaInN), and the transformed part may be a part where one of ion species of boron (B), aluminium (Al), and gallium (Ga) is implanted and where a composition ratio of the one of ion species of boron (B), aluminium (Al), and gallium (Ga) in the active layer is greater than an average composition ratio of the one of ion species of boron (B), aluminium (Al), and gallium (Ga) in the active layer.

With the above structure, it is possible to further increase the bandgap of the transformed part.

Here, the transformed part may be a part where ion species including In and one of boron (B), aluminium (Al), and gallium (Ga) are implanted.

With the above structure, the effect of In for reducing the bandgap is reversed with the effect of B, Al, and Ga for increasing the bandgap, so that it is possible to maximize the disordering effect by diffusing In.

Here, a refractive index of the transformed part is equivalent to a refractive index of parts except the transformed part.

Here, a method of manufacturing a nitride semiconductor laser device which is made of a nitride semiconductor device, the nitride semiconductor laser having a resonator which causes laser oscillation, the method may include: forming, on a substrate, a semiconductor layer which is made of the nitride semiconductor; and forming a transformed part by transforming a part in the semiconductor layer, the part being to be an end part of the resonator in a resonance direction, and in the forming of the semiconductor layer, an n-type cladding layer and an active layer may be sequentially formed on the substrate by a crystal growth method, and in the forming of the transformed part, the transformed part is formed at a part in the active layer, the part being to be an end part of the resonator in a resonance direction, the method further including: heating the transformed part to be disordered; forming a p-type cladding layer by the crystal growth method above the active layer in which the disordered transformed part is formed; and forming a stripe-shaped ridge part in the p-type cladding layer.

With the above structure, it is possible to manufacture a nitride semiconductor having the disordered transformed part and the ridge-stripe-shaped waveguide.

Here, in the heating, the transformed part may be heated to have a temperature that is equal to or higher than 800° C., and in the heating, the transformed part may be heated by irradiating a laser beam.

With the above structure, it is possible to restore the damage resulted from the transformed part formation and to disorder the active layer.

Here, in the forming of the semiconductor layer, an n-type cladding layer, an active layer, and a p-type cladding layer may be sequentially formed on the substrate by a crystal growth method, and in the forming of the transformed part, the transformed part is formed at a part in the p-type cladding layer, the part being to be an end part of the resonator in a resonance direction, the method may further include forming a stripe-shaped ridge part in the p-type cladding layer so that the transformed part is formed as the ridge part.

With the above structure, it is possible to manufacture a nitride semiconductor laser device having the transformed part and the ridge-stripe-shaped waveguide.

Here, the method of manufacturing the semiconductor layer may further include activating a p-type impurity in the p-type cladding layer, and wherein in the forming of the transformed part, the transformed part is formed in the p-type cladding layer where the activating of the p-type impurity is performed. Furthermore, the temperature of the substrate and the semiconductor layer may be maintained to have a temperature of 800° C. or less, after forming the transformed part.

With the above structure, it is possible to manufacture a nitride semiconductor laser device without deterioration of a p-type layer, by effectively activating the p-type layer.

Here, in the forming of the semiconductor layer, an n-type cladding layer, an active layer, and a blocking layer may be sequentially formed on the substrate by a crystal growth method, and then a stripe-shaped opening is formed in the blocking layer, and in the forming of the transformed part, the transformed part is formed at a part in the active layer, the part being to be an end part of the resonator in a resonance direction, and the method may further include: heating the transformed part to be disordered; and forming, after the heating, a p-type cladding layer by growing the p-type cladding layer from the opening by the crystal growth method.

With the above structure, it is possible to manufacture a nitride semiconductor laser device having the disordered transformed part and the embedded-stripe-shaped waveguide.

Here, in the heating, the transformed part may be heated to have a temperature that is equal to or higher than 800° C. Furthermore, in the heating, the transformed part may be heated by irradiating a laser beam. Still further, in the forming of the semiconductor layer, an n-type cladding layer, an active layer, and a blocking layer may be sequentially formed on the substrate by a crystal growth method, then a stripe-shaped opening is formed in the blocking layer, and then the p-type cladding layer is grown from the opening by the crystal growth method, and in the forming of the transformed part, the transformed part is formed at a part in the p-type cladding layer in the opening, the part being to be an end part of the resonator in a resonance direction.

With the above structure, it is possible to manufacture a nitride semiconductor laser device having the transformed part and the embedded-stripe-shaped waveguide.

Here, in the forming of the transformed part, the transformed part may be formed by applying ion implantation at a part where the transformed part is to be formed, during heating the substrate and the semiconductor layer to have a temperature that is equal to or higher than 400° C.

With the above structure, it is possible to reduce the damage resulted from the ion implantation.

Here, in the forming of the transformed part, the ion implantation may be performed during irradiating a laser beam at a part where the ion implantation is applied.

With the above structure, it is possible to selectively heat a region positioned closely to a sample surface to be applied with ion implantation, so that it is possible to reduce the damage resulted from the ion implantation.

Regarding the nitride semiconductor laser device and the manufacturing method thereof according to the present invention, it is possible to restrain the heating on the resonator end part which is caused by light absorption, current injection, and the like, by using the transformed part which is formed closely to the resonator end surface by being disordered or by increasing resistance, thereby enabling to restrain the COD and the resonator end surface deterioration, so that it is possible to realize a reliable nitride semiconductor laser device having high output and long lifetime. Furthermore, by implanting a plurality of ion species together, it is possible to realize a nitride semiconductor laser device having a structure in which the disordered and high-resistivity transformed part is formed, so that a high-quality nitride semiconductor laser device can be manufactured by simple processing.

### FURTHER INFORMATION ABOUT TECHNICAL BACKGROUND TO THIS APPLICATION

The disclosure of Japanese Patent Application No. 2005-016177 filed on Jan. 24, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of the conventional blue nitride semiconductor laser device which is disclosed in “High-Power, Long-Life InGaN/GaN/AlGaN-based Laser Diodes Grown on Pure GaN Substrates”;

FIG. 2 is cross-sectional views of a structure of the conventional window structure infrared laser device which is described in Japanese Patent Publication No. 6-48742;

FIG. 3 is a perspective view of a nitride semiconductor laser device according to the first embodiment;

FIG. 4(a) is a cross-sectional view of the nitride semiconductor laser device taken along line B-B′ of FIG. 3, according to the first embodiment;

FIG. 4(b) is a cross-sectional view of the nitride semiconductor laser device taken along line A-A′ of FIG. 3, according to the first embodiment;

FIG. 5 shows cross-sectional views for explaining a method of manufacturing the nitride semiconductor laser device according to the first embodiment;

FIG. 6 is a cross-sectional view showing the method of manufacturing the nitride semiconductor laser device according to the first embodiment;

FIG. 7 is a perspective view of a nitride semiconductor laser device according to the second embodiment;

FIG. 8(a) is a cross-sectional view of the nitride semiconductor laser device taken along line B-B′ of FIG. 7, according to the second embodiment;

FIG. 8(b) is a cross-sectional view of the nitride semiconductor laser device taken along line A-A′ of FIG. 7, according to the second embodiment;

FIG. 9 shows cross-sectional views for explaining a method of manufacturing the nitride semiconductor laser device according to the second embodiment;

FIG. 10 is a perspective view of a nitride semiconductor laser device according to the third embodiment;

FIG. 11(a) is a cross-sectional view of the nitride semiconductor laser device taken along line B-B′ of FIG. 10, according to the third embodiment;

FIG. 11(b) is a cross-sectional view of the nitride semiconductor laser device taken along line A-A′ of FIG. 10, according to the third embodiment;

FIG. 12 shows cross-sectional views for explaining a method of manufacturing the nitride semiconductor laser device according to the third embodiment;

FIG. 13 is a cross-sectional views showing the method of manufacturing the nitride semiconductor laser device according to the third embodiment;

FIG. 14 is a perspective view of a nitride semiconductor laser device according to the fourth embodiment;

FIG. 15(a) is a cross-sectional view of the nitride semiconductor laser device taken along line B-B′ of FIG. 14, according to the fourth embodiment;

FIG. 15(b) is a cross-sectional view of the nitride semiconductor laser device taken along line A-A′ of FIG. 14, according to the fourth embodiment; and

FIG. 16 shows cross-sectional views for explaining a method of manufacturing the nitride semiconductor laser device according to the fourth embodiment.

### DESCRIPTION OF THE PREFERRED EMBODIMENT(S)

### First Embodiment

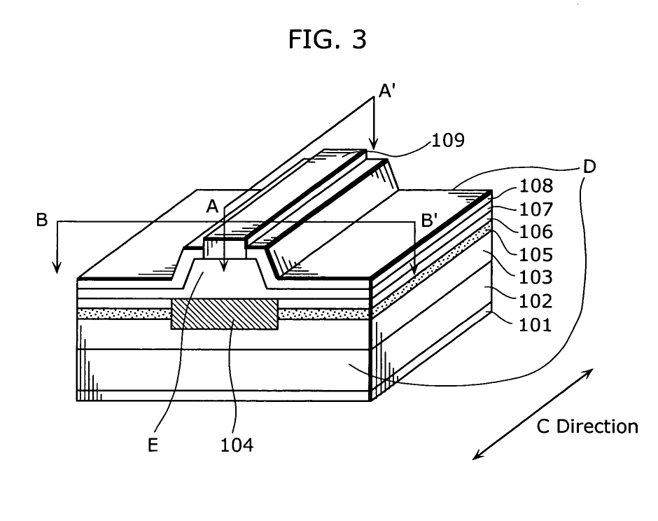

The following describes in detail a nitride semiconductor laser device and a manufacturing method thereof according to the first embodiment with reference to FIGS. 3 to 6. The first embodiment describes a nitride semiconductor laser device having a window structure formed by ion implantation and a ridge-stripe-shaped waveguide. Note that the window structure is a structure formed by disordering an active layer at an end part of the resonator in a resonance direction in order to form a part which does not absorb resonated light. Note also that the ridge-stripe-shaped waveguide is a waveguide having a stripe-shaped ridge parallel to the resonance direction.

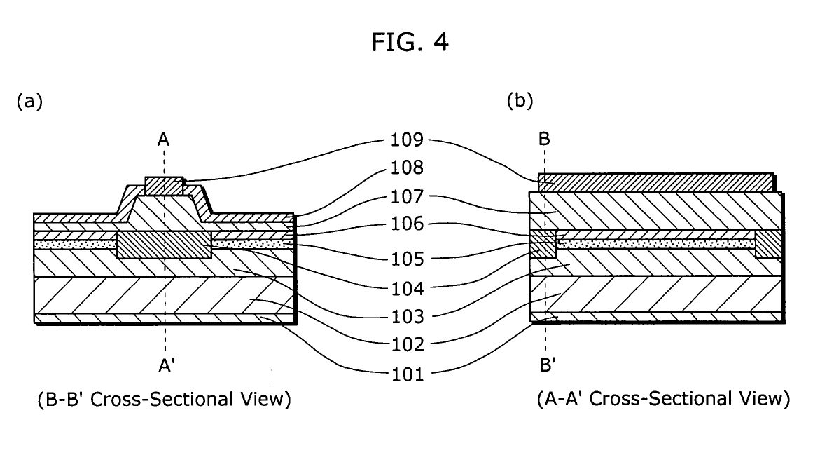

FIG. 3 is a perspective view of the nitride semiconductor laser device according to the first embodiment. FIG. 4(a) is a cross-sectional view of the nitride semiconductor laser device from the resonance direction of the resonator (C direction of FIG. 3), taken along line B-B′ of FIG. 3. FIG. 4(b) is a cross-sectional view of the nitride semiconductor laser device from a direction perpendicular to the resonance direction of the resonator, taken along line A-A′ of FIG. 3.

The semiconductor laser device according to the first embodiment includes: a n-electrode 101 which is made of Ti/Al/Ni/Au; a n-type GaN substrate 102; a first cladding layer 103 which is made of n-type GaN or n-type AlGaN; an ion implanted part 104; an active layer 105 which has an AlGaInN multiple quantum well; a second cladding layer 106 which is made of p-type or undoped GaN, or p-type or undoped AlGaN; a third cladding layer 107 which is made of p-type GaN or p-type AlGaN; a dielectric insulating film 108 which is made of SiO₂; and a p-electrode 109 which is made of Ni/Pt/Au. Note that the ion implanted part 104 is one example of a transformed part according to the present invention.

Here, the first cladding layer 103, the active layer 105, the second cladding layer 106, the third cladding layer 107, and the dielectric insulating film 108 form a resonator which causes laser oscillation.

The semiconductor laser device according to the first embodiment is a blue-violet semiconductor laser device made of a nitride semiconductor having a ridge-stripe-shaped waveguide. The semiconductor laser device has a disordered region (ion implanted part 104) which is formed at a region (resonator end part) positioned closely to an end surface D of the resonator (resonator end surface) in a resonance direction, by applying ion implantation and then thermal annealing to the second cladding layer 106, the active layer 105, and a part of the first cladding layer 103. The semiconductor laser device also has the third cladding layer 107 formed by re-growing the nitride semiconductor after forming the disordered region. That is, the nitride semiconductor laser device according to the first embodiment is a blue-violet semiconductor laser device in which a disordered region (ion implanted part 104) is formed by transforming a semiconductor layer positioned below the third cladding layer 107 as a p-type semiconductor layer in the resonator end parts which sandwich the middle part of the resonator where light is resonated.

For example, on the n-type GaN substrate 102 are sequentially stacked; the first cladding layer 103 which is made of n-type AlₓGa₁₋ₓN (where 0≦xw≦1); the InGaN multiple quantum well active layer 105 which is made of an In_{1-xb}Ga_{xb}N (where 0≦xb≦1) barrier layer and an In_{1-xw}Ga_{xw}N (where 0≦xw≦1) well layer; the second cladding layer 106 which is made of p-type or undoped GaN, or p-type or undoped AlₓGa₁₋ₓN; and the third cladding layer 107 which is made of p-type AlₓGa₁₋ₓN. The third cladding layer 107 has a stripe-shaped ridge part (E in FIG. 3). On a side surface of the ridge part and on a top surface of a non-ridge part in the third cladding layer 107, the dielectric insulating film 108 made of SiO₂ is formed. On a top surface of the ridge part, an ohmic electrode made of Ni/Pt/Au is formed as the p-electrode 109. On a rear surface of the n-type GaN substrate 102, an ohmic electrode made of Ti/Al/Ni/Au is formed as the n-electrode 101. Furthermore, regarding the resonator end part, the ion implanted part 104 is formed in the second cladding layer 106, the active layer 105, and a part of the first cladding layer 103. The first cladding layer 103 as a n-type layer is doped with silicon (Si) as impurity, and on the other hand, the second cladding layer 106 (in a case of p-type) and the third cladding layer 107 as p-type layers are doped with magnesium (Mg) as impurity. The ion implanted part 104 is formed by being implanted with aluminium (Al) by an impurity concentration of 1×10¹⁵ cm⁻². The ion implanted part 104 is applied with thermal annealing of 1000° C. after the ion implantation, so that the active layer 105 in the ion implanted part 104 is disordered until an bandgap of the active layer 105 in the ion implanted part 104 is increased but the active layer 105 does not absorb blue-violet light (wavelength of about 405 nm).

As described above, according to the nitride semiconductor laser device of the first embodiment, at the resonator end part, the active layer 105 is disordered to form the ion implanted part 104 where the bandgap of the active layer 105 is increased. As a result, light is not absorbed at the resonator end part, thereby enabling to restrain the COD during high-output operation, the resonator end surface deterioration, and the like, so that it is possible to realize a nitride semiconductor laser device having high output and long lifetime.

Note that, for the nitride semiconductor laser device according to the first embodiment, an ion specie implanted to form the ion implanted part 104 is described as Al, but the ion specie may be another ion specie, such as hydrogen (H), boron (B), carbon (C), nitrogen (N), silicon (Si), zinc (Zn), gallium (Ga), arsenic (As), or Indium (In). Note also that the amount of implanted ion specie is desirably from 1×10¹⁴ cm⁻² to 1×10¹⁶ cm⁻².

For example, when ion specie such as H, B, C, N, or Zn is implanted, the ion implanted part 104 becomes a high-resistivity part in the active layer 105, the first cladding layer 103, and the second cladding layer 106, which makes it possible to expect not only the light transmission effect of making the end part not to absorb light emitted from the active layer 105 but also high resistance effect, namely, an effect of forming the resonator end part as a current non-injected region, so that it is possible to expect higher output and longer lifetime of the laser device. On the other hand, when Si is implanted as the ion specie, the ion implanted part 104 becomes n-type, so that if all layers adjacent to the ion implanted part 104 are p-type, a p-n-p junction is formed, which makes it possible to expect the same effect as described above obtained by forming the resonator end part as the current non-injected region. Moreover, when a III group ion specie such as B, Al, Ga, or In is implanted, it is possible to control to set a composition ratio of a III group element in the ion implanted part 104 to be greater than a composition ratio of an III group element in the active layer 105 by disordering, so that window structure tuning becomes possible. When a wavelength is tuned by implanting the III group ion specie, it is preferable to implant an ion specie of a large amount that is 1×10¹⁶ cm⁻² or more. By implanting such a large amount of an ion specie, it is possible to change the composition ratio of the III group element in the ion implanted part 104.

Moreover, the ion specie implanted to form the ion implanted part 104 may be two or more ion species. For example, by implanting a III group element such as Al together with In, or by implanting a III group element such as Al together with Zn, it is possible to realize a window structure having better characteristics. More specifically, when Al and In are implanted at the same time, In has more mass and more diffusion coefficient in GaN compared to Al, so that In is suitable to disorder the active layer 105. However, In has an effect of reducing a gandgap of the active layer 105. Therefore, In is implanted together with Al having the same amount as the In, so that it is possible to compensate the effect of In and to increase the bandgap of the active layer 105. In other words, it is possible to form the ion implanted part 104 which does not absorb light. On the other hand, when Al and Zn are implanted at the same time, it is possible to expect a bandgap increase effect from Al and a high resistance effect from Zn, so that it is possible to realize a window structure having both of the light transmission effect and the high resistance effect.

Furthermore, according to the nitride semiconductor laser device of the first embodiment, the window structure is formed by applying ion implantation to a semiconductor layer. Therefore, since there is almost no difference between refractive index of the ion implanted part 104 and refractive index of the ion non-implanted part, an light confinement structure including the active layer 105, the ridge-stripe-shaped waveguide, and the dielectric insulating film 108 in the laser device is almost similar to an light confinement structure including the ion implanted part 104 at the resonator end part, so that it is possible to realize reliable laser oscillation.

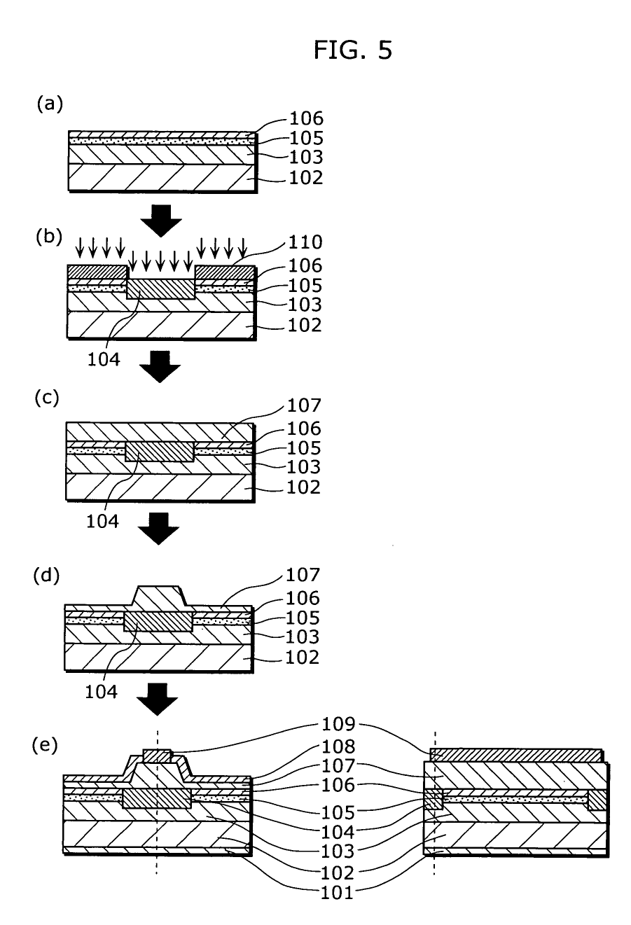

In order to manufacture the nitride semiconductor laser device having the structure as shown in FIGS. 3 and 4, a manufacturing method shown in FIG. 5, for example, is conceived. FIG. 5 shows cross-sectional views for explaining the method of manufacturing the nitride semiconductor laser device according to the first embodiment of the present invention. In FIG. 5, the same components are designated by the same reference numerals in FIGS. 3 and 4, and the structures of those components are the same as described above.

Firstly, for example, on a (0001) plane of the n-type GaN substrate 102 having a dislocation density in a range of 10⁶ cm⁻³, using a crystal growth method such as a metal organic chemical vapor deposition (MOCVD) method, sequentially are stacked: a n-type GaN buffer layer (not shown); the first cladding layer 103 made of n-type GaN or n-type AlGaN; the InGaN multiple quantum well active layer 105; and the second cladding layer 106 made of p-type or undoped GaN, or p-type or undoped AlGaN (FIG. 5(a)). The active layer 105 emits blue-violet light having a wavelength of 405 nm by current injection.

Next, on the second cladding layer 106, a SiO₂ mask 110 having an opening formed only at the resonator end part is formed. Then, the opening is applied with ion implantation at an accelerating voltage using, for example, Al ion. Thereby the voltage makes the ion reach the active layer 105 and a part of the first cladding layer 103. As a result, the ion implanted part 104 can be formed at a part which is to be the resonator end part in the first cladding layer 103 and the active layer 105 (FIG. 5 (b)). An amount of the implanted ion is 1×10¹⁵ cm⁻², for example. After that, the ion implanted part 104 is applied with heat treatment of 800° C. or higher, for example thermal annealing of 1000° C. or higher, so that damage on the ion implanted part 104 is restored and the active layer 105 at the resonator end part is disordered by diffusing the implanted ion in the ion implanted part 104.

Next, on the second cladding layer 106, the third cladding layer 107 made of p-type AlGaN is re-grown using the crystal growth method such as the MOCVD method. After that, the second cladding layer 106 (in a case of p-type) and the third cladding layer 107 are applied with thermal annealing in the nitrogen dioxide (N₂) atmosphere, for example with 750° C. and 30 minutes, in order to activate p-type impurity in the second cladding layer 106 (in a case of p-type) and the third cladding layer 107 (FIG. 5 (c)).

Next, after activating the p-type impurity, on the third cladding layer 107, a photoresist (not shown) having a stripe-shaped opening is formed. Using the photoresist as a mask, in the third cladding layer 107, a stripe-shaped ridge part is formed by performing, for example, dry etching called inductive coupled plasma (ICP) dry etching using CI₂ gas (FIG. 5 (d)).

Next, on the third cladding layer 107, the dielectric insulating film 108 made of SiO₂ is formed. Then using photolithography patterning and wet etching, an opening is formed only above the ridge part of the third cladding layer 107. After that, at the opening above the ridge part, a Ni/Pt/Au electrode is formed using, for example, electron beam (EB) evaporation and liftoff. Here, in order to reduce contact resistance regarding the p-type layer, sintering of 600° C. in the N₂ atmosphere is performed to form an ohmic electrode (p-electrode 109).

Next, the n-type GaN substrate 102 is polished up to a thickness of about 150 μm from the rear surface. Then, on the rear surface of the n-type GaN substrate 102, a Ti/Al/Ni/Au electrode is formed using, for example, the EB evaporation and liftoff. Here, in order to reduce contact resistance regarding the n-type layer, sintering of 600° C. in the N₂ atmosphere is performed to form an ohmic electrode (n-electrode 101). Thus, the nitride semiconductor laser device having the structure as shown in FIGS. 3 and 4 is formed (FIG. 5 (e)).

As described above, according to the method of manufacturing the nitride semiconductor laser device of the first embodiment, the p-type layer (third cladding layer 107) is formed by the re-growth, after forming the window structure using the ion implantation and the thermal annealing. Therefore, without exposing the p-type layer (third cladding layer 107) to a high temperature of 800° C. or higher, the nitride semiconductor laser device having the window structure can be manufactured, so that it is possible to realize a nitride semiconductor laser device having high output and long lifetime.

Note that, in the above method of manufacturing the nitride semiconductor laser device, Al is used as an example of the ion specie implanted to form the ion implanted part 104, however, the ion specie may be another ion specie such as H, B, C, N, Si, Zn, Ga, As, or In. Furthermore, a plurality of ion species may be implanted at the same time. The amount of implanted ion specie is desirably within a range from 1×10¹⁴ cm⁻² to 1×10¹⁶ cm⁻², and when III group ion specie such as Al, Ga, or In is implanted, the amount is preferably 1×10¹⁶ cm⁻² or more

Note also that, during the ion implantation shown in FIG. 5(b), the n-type GaN substrate 102 and the semiconductor layer may be heated to have a temperature of 400° C. or higher. Thereby lattice energy of the n-type GaN substrate 102 becomes high thereby reducing crystalline damage during the ion implantation, so that it is possible to improve light transmission characteristics of the window structure.

Here, during the ion implantation, laser may be irradiated on the part where the ion implanted part 104 is to be formed. Note that the laser has energy greater than a bandgap of the part where the ion implanted part 104 is to be formed. Examples of such laser are a KrF laser (wavelength 248 nm), the third harmonic of pulsed YAG laser having a wave (wavelength 355 nm), and the like. Thereby it is possible to selectively heat only the part where the ion implanted part 104 is to be formed, thereby reducing the crystalline damage during the ion implantation, so that it is possible to improve the light transmission characteristics of the window structure.

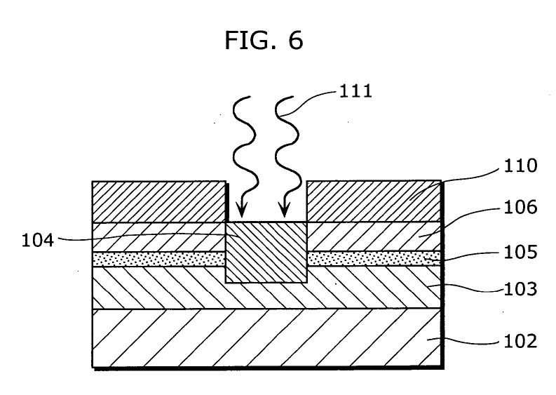

Note also that, during the heat treatment after the ion implantation shown in FIG. 5 (b), the ion implanted part 104 may be irradiated by laser 111, such as the KrF laser (wavelength 248 nm) or the the third harmonic of pulsed YAG laser having a wave (wavelength 355 nm), as shown in FIG. 6, in order to heat the part where the ion implanted part 104 is to be formed to have a temperature of 800° C. or higher. Thereby it is possible to selectively heat only the part where the ion implanted part 104 is to be formed.

### Second Embodiment

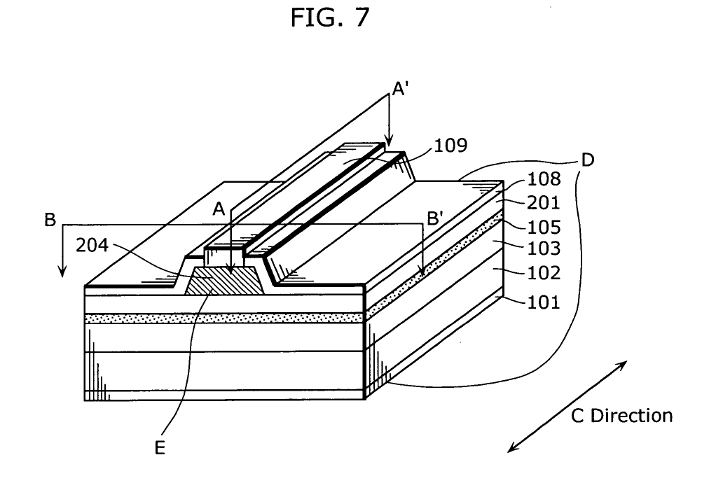

The following describes in detail a nitride semiconductor laser device and a manufacturing method thereof according to the second embodiment with reference to FIGS. 7 to 9. The second embodiment describes a nitride semiconductor laser device having a ridge-stripe-shaped waveguide and a high-resistivity current-non-injected region formed using ion implantation.

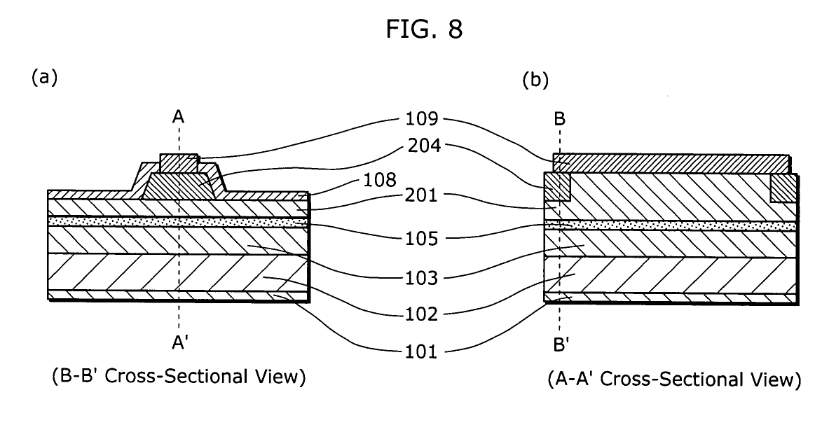

FIG. 7 is a perspective view of the nitride semiconductor laser according to the second embodiment. FIG. 8(a) is a cross-sectional view of the nitride semiconductor laser device from the resonance direction of the resonator (C direction of FIG. 7), taken along line B-B′ of FIG. 7. FIG. 8(b) is a cross-sectional view of the nitride semiconductor laser device from a direction from a direction perpendicular to the resonance direction of the resonator, taken along line A-A′ of FIG. 7. In FIGS. 7 and 8, the same components are designated by the same reference numerals in FIGS. 3 and 4, and the structures of those components are the same as described above.

The semiconductor laser device according to the second embodiment includes: the n-electrode 101; the n-type GaN substrate 102; the first cladding layer 103; an ion implanted part 204; the active layer 105; a third cladding layer 201 which is made of p-type GaN or p-type AlGaN; the dielectric insulating film 108; and the p-electrode 109. Note that the ion implanted part 204 is one example of a transformed part according to the present invention.

Here, the first cladding layer 103, the active layer 105, the third cladding layer 201, and the dielectric insulating film 108 form a resonator which causes laser oscillation.

The semiconductor laser device according to the second embodiment is a blue-violet semiconductor laser device made of a nitride semiconductor having a ridge-stripe-shaped waveguide. The semiconductor laser device has a high-resistivity region (ion implanted part 204) formed at a region (resonator end part) positioned closely to a resonator end surface D, by applying ion implantation to a part of the third cladding layer 201. That is, the nitride semiconductor laser device according to the second embodiment is a blue-violet semiconductor laser device in which a current non-injected region is formed by transforming a semiconductor layer positioned above the active layer 105 in the resonator end parts which sandwich the middle part of the resonator where light is resonated.

For example, on the n-type GaN substrate 102 are sequentially stacked; the first cladding layer 103 which is made of n-type AlₓGa₁₋ₓN (where 0≦x≦=1); the InGaN multiple quantum well active layer 105 which is made of an In_{1-xb}Ga_{xb}N (where 0≦xb≦1) barrier layer and an In_{1-xw}Ga_{xw}N (where 0≦xw≦1) well layer; and the third cladding layer 201 which is made of p-type AlₓGa₁₋ₓN. The third cladding layer 201 has a stripe-shaped ridge part (E in FIG. 5). On a side surface of the ridge part and on a top surface of a non-ridge part in the third cladding layer 201, the dielectric insulating film 108 made of SiO₂ is formed. On a top surface of the ridge part, an ohmic electrode made of Ni/Pt/Au is formed as the p-electrode 109. On a rear surface of the n-type GaN substrate 102, an ohmic electrode made of Ti/Al/Ni/Au is formed as the n-electrode 101.

Furthermore, regarding the resonator end part, the ion implanted part 204 is formed at a part of the third cladding layer 201. The first cladding layer 103 as an n-type layer is doped with Si as impurity, and on the other hand, the third cladding layer 201 as a p-type layer is doped with Mg as impurity. The ion implanted part 204 is implanted with Zn by an impurity concentration of 1×10¹⁵ cm⁻². The ion implanted part 204 is formed only in the third cladding layer 201, not in the active layer 105. Furthermore, using ion implantation, resistance of the ion implanted part 204 is increased in order to have specific resistance of 10⁸ Ωcm or more for example, so that the ion implanted part 204 has a function as a current injection blocking layer for blocking current injected in the resonator end part.

As described above, according to the nitride semiconductor laser device of the second embodiment, the ion implanted part 204 has a function as a current injection blocking layer for blocking current injected in the resonator end part. As a result, heating is restrained at the resonator end part, thereby enabling to restrain the COD during high-output operation, the resonator end surface deterioration, and the like, so that it is possible to realize a laser device having high output and long lifetime.

Furthermore, according to the nitride semiconductor laser device of the second embodiment, the current non-injected region is formed by applying ion implantation to a semiconductor layer. Therefore, since there is almost no difference between refractive index of the ion implanted part 204 and refractive index of the ion non-implanted part, the current non-injected region can be formed without changing a structure of the waveguide at the resonator end part, so that it is possible to realize a reliable single horizontal mode operation.

Note that, for the nitride semiconductor laser device according to the second embodiment, an ion specie implanted to form the ion implanted part 204 is described as Zn, but as far as the resistance of third cladding layer 201 can be increased by the ion implantation, the ion specie may be another ion specie, such as H, B, C, N, Al, Si, Ga, As, or In. In the nitride semiconductor laser device according to the second embodiment, thermal annealing with a high temperature of higher than 800° C. is not performed after the ion implantation, so that the ion specie is not limited to Zn as far as the resistance is not reduced due to heat treatment with a relatively low temperature of 600° C. or less in other processing. For example, when Si is implanted as the ion specie, the ion implanted part 204 becomes n-type, so that since all layers adjacent to the ion implanted part 204 are p-type, a p-n-p junction is formed, which makes it possible to expect the same effect as described above obtained by forming the resonator end part as the current non-injected region. The amount of implanted ion specie is desirably within a range from 1×10¹⁴ cm⁻² to 1×10¹⁶ cm⁻². Moreover, the ion specie implanted to the ion implanted part 204 may be two or more ion species.

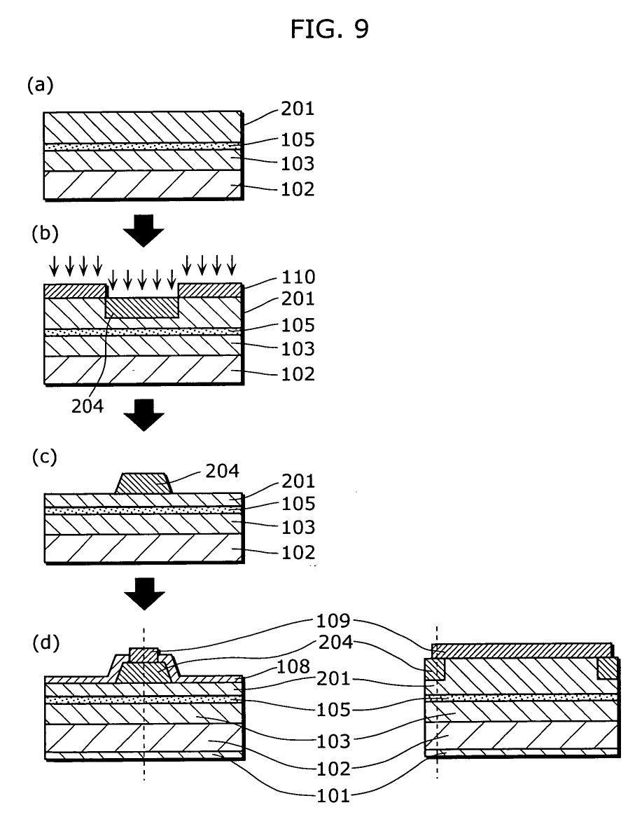

In order to manufacture the nitride semiconductor laser device having the structure as shown in FIGS. 7 and 8, a manufacturing method shown in FIG. 9, for example, is conceived. FIG. 9 shows cross-sectional views for explaining the method of manufacturing the nitride semiconductor laser device according to the second embodiment of the present invention. In FIG. 9, the same components are designated by the same reference numerals in FIGS. 7 and 8, and the structures of those components are the same as described above.

Firstly, for example, on a (0001) plane of the n-type GaN substrate 102 having a dislocation density in a range of 10⁶ cm⁻³, using the crystal growth method such as the MOCVD method, sequentially are stacked: the n-type GaN buffer layer (not shown); the first cladding layer 103 made of n-type GaN or n-type AlGaN; the InGaN multiple quantum well active layer 105; and the third cladding layer 201 made of p-type GaN or p-type AlGaN (FIG. 9(a)). The active layer 105 emits blue-violet light having a wavelength of 405 nm by current injection. After that, the third cladding layer 201 is applied with thermal annealing in the N₂ atmosphere, for example with 750° C. and 30 minutes, in order to activate p-type impurity in the third cladding layer 201.

Next, on the third cladding layer 201, a SiO₂ mask 110 having an opening formed only at the resonator end part is formed. Then, the third cladding layer 201 is applied with ion implantation at an accelerating voltage using Zn ion, for example, although the voltage does not make the ion reach the active layer 105, so that the ion implanted part 204 can be formed at a part which is to be the resonator end part in the third cladding layer 201 (FIG. 9 (b)). An amount of the implanted ion is 1×10¹⁵ cm⁻², for example.

Next, in order to form the ion implanted part 204 to be a ridge-shaped part, on the third cladding layer 201, a stripe-shaped ridge part is formed. More specifically, on the third cladding layer 201, a photoresist (not shown) having a stripe-shaped opening is formed. Using the photoresist as a mask, the stripe-shaped ridge part is formed in the third cladding layer 201 by performing, for example, the ICP dry etching using CI₂ gas (FIG. 9 (c)).

Next, on the third cladding layer 201, the dielectric insulating film 108 made of SiO₂ is formed. Then using photolithography patterning and wet etching, an opening is formed only above the ridge part of the third cladding layer 201. After that, at the opening above the ridge part, a Ni/Pt/Au electrode is formed using, for example, EB evaporation and liftoff. Here, in order to reduce contact resistance regarding the p-type layer, sintering of 600° C. in the N₂ atmosphere is performed to form an ohmic electrode (p-electrode 109).

Next, the n-type GaN substrate 102 is polished up to a thickness of about 150 μm from the rear surface. Then, on the rear surface of the n-type GaN substrate 102, a Ti/Al/Ni/Au electrode is formed using, for example, the EB evaporation and liftoff. Here, in order to reduce contact resistance regarding the n-type layer, sintering of 600° C. in the N₂ atmosphere is performed to form an ohmic electrode (n-electrode 101). Thus, the nitride semiconductor laser device having the structure as shown in FIGS. 7 and 8 is formed (FIG. 9(d)).

As described above, according to the method of manufacturing the nitride semiconductor laser device of the second embodiment, the current non-injected region is formed by increasing resistance, using the ion implantation which does not reach the active layer 105. Therefore, without performing thermal annealing of a high temperature in order to restore damage resulted from ion implantation, it is possible to manufacture the nitride semiconductor laser device having the structure with the current non-injected region at the resonator end part, so that it is possible to realize a blue-violet nitride semiconductor laser device having high output and long lifetime.

Note that, in the above method of manufacturing the nitride semiconductor laser device, Zn is used as an example of the ion specie implanted to form the ion implanted part 204, however, the ion specie may be another ion specie such as H, B, C, N, Al, Si, Ga, As, or In. The amount of implanted ion specie is desirably within a range from 1×10¹⁴ cm⁻² to 1×10¹⁶ cm⁻².

Note also that, during the ion implantation shown in FIG. 9(b), the n-type GaN substrate 102 and the semiconductor layer may be heated to have a temperature of 400° C. or higher. Thereby lattice energy of the n-type GaN substrate 102 becomes, so that it is possible to reduce crystalline damage during the ion implantation.

Here, during the ion implantation, it is possible to irradiate laser on the part where the ion implanted part 204 is to be formed. Note that the laser has energy greater than a bandgap of the part where the ion implanted part 204 is to be formed. Examples of such laser are a KrF laser (wavelength 248 nm), the third harmonic of pulsed YAG laser having a wave (wavelength 355 nm), and the like. Thereby it is possible to selectively heat only the part where the ion implanted part 204 is to be formed, thereby reducing the crystalline damage during the ion implantation, so that it is possible to reduce the crystalline damage during the ion implantation.

### Third Embodiment

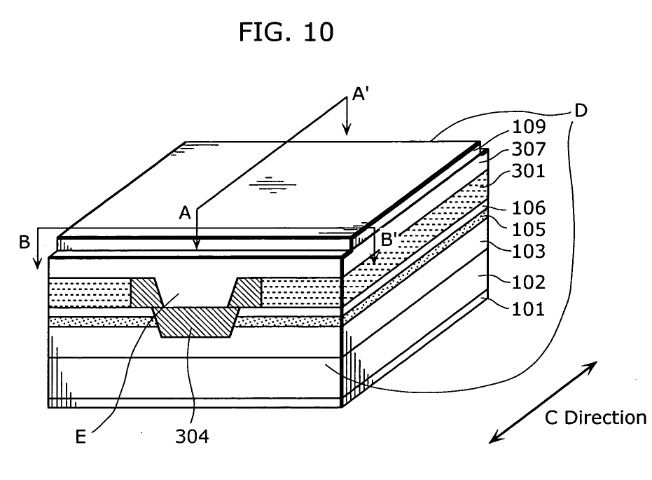

The following describes in detail a nitride semiconductor laser device and a manufacturing method thereof according to the third embodiment with reference to FIGS. 10 to 13. The third embodiment describes a nitride semiconductor laser device having a window structure formed by ion implantation and an embedded-stripe-shaped waveguide. Note that the embedded-stripe-shaped waveguide is a waveguide which is embedded in a semiconductor layer and has a stripe shape parallel to a resonance direction.

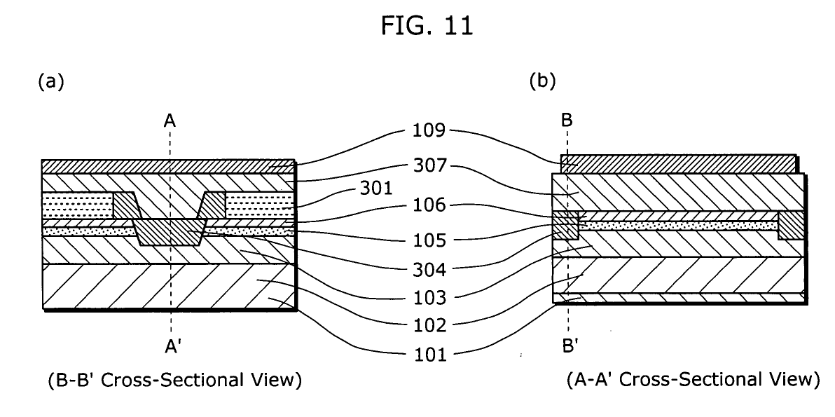

FIG. 10 is a perspective view of the nitride semiconductor laser device according to the third embodiment. FIG. 11(a) is a cross-sectional view of the nitride semiconductor laser device from the resonance direction of the resonator (C direction of FIG. 10), taken along line B-B′ of FIG. 10. FIG. 11(b) is a cross-sectional view of the nitride semiconductor laser device from a direction from a direction perpendicular to the resonance direction of the resonator, taken along line A-A′ of FIG. 10. In FIGS. 10 and 11, the same components are designated by the same reference numerals in FIGS. 3 and 4, and the structures of those components are the same as described above.

The semiconductor laser device according to the third embodiment includes: the n-electrode 101; the n-type GaN substrate 102; the first cladding layer 103; an ion implanted part 304; the active layer 105; the second cladding layer 106; a third cladding layer 307 which is made of p-type GaN or p-type AlGaN; a current blocking layer 301 which is made of n-type or undoped AlGaN; and the p-electrode 109. Note that the ion implanted part 304 is one example of a transformed part according to the present invention.

Here, the first cladding layer 103, the active layer 105, the second cladding layer 106, the third cladding layer 307, and the current blocking layer 301 form a resonator which causes laser oscillation.

The semiconductor laser device according to the third embodiment is a blue-violet semiconductor laser device made of a nitride semiconductor having the embedded-stripe-shaped waveguide. The semiconductor laser device has a disordered region (ion implanted part 304) which is formed at a region (resonator end part) positioned closely to a resonator end surface D by applying ion implantation and then thermal annealing to the current blocking layer 301, the second cladding layer 106, the active layer 105, and a part of the first cladding layer 103. The semiconductor laser device also has the third cladding layer 307 formed by re-growing the nitride semiconductor after forming the disordered region. That is, the nitride semiconductor laser device according to the third embodiment is a blue-violet semiconductor laser device in which a disordered region (ion implanted part 304) is formed by transforming a semiconductor layer positioned below the third cladding layer 307 as a p-type semiconductor layer in the resonator end parts which sandwich the middle part of the resonator where light is resonated.

For example, on the n-type GaN substrate 102 are sequentially stacked; the first cladding layer 103 which is made of n-type AlₓGa₁₋ₓN (where 0≦x≦1); the InGaN multiple quantum well active layer 105 which is made of an In_{1-xb}Ga_{xb}N (where 0≦xb≦1) barrier layer and an In_{1-xw}Ga_{xw}N (where 0≦xw≦1) well layer; the second cladding layer 106 which is made of p-type or undoped GaN, or p-type or undoped AlₓGa₁₋ₓN; the current blocking layer 301 which is made of n-type or undoped Al_{y}Ga_{1-y}N (where 0≦xy≦1); and the third cladding layer 307 which is made of p-type AlₓGa₁₋ₓN. The current blocking layer 301 has a stripe-shaped opening (E in FIG. 10). On a top surface of the third cladding layer 307, an ohmic electrode made of Ni/Pt/Au is formed as the p-electrode 109. On a rear surface of the n-type GaN substrate 102, an ohmic electrode made of Ti/Al/Ni/Au is formed as the n-electrode 101. Furthermore, regarding the resonator end part, the ion implanted part 304 is formed in a part of the first cladding layer 103, the active layer 105, the second cladding layer 106, and a part of the current blocking layer 301. The first cladding layer 103 and the current blocking layer 301 (in a case of n-type) as n-type layers are doped with Si as impurity, and on the other hand, the second cladding layer 106 (in a case of p-type) and the third cladding layer 307 as p-type layers are doped with Mg as impurity. The ion implanted part 304 is formed by being implanted with Al by an impurity concentration of 1×10¹⁵ cm⁻².

The ion implanted part 304 is formed by the ion implantation and then thermal annealing of 1000° C., and the active layer 105 in the ion implanted part 304 is disordered, so that an bandgap of the active layer 105 in the ion-implanted part 304 is increased but the active layer 105 does not absorb blue-violet light (wavelength of about 405 nm).

As described above, according to the nitride semiconductor laser device of the third embodiment, at the resonator end part, the active layer 105 is disordered to form the ion implanted part 304 where the bandgap of the active layer 105 is increased. As a result, light is not absorbed at the resonator end part, thereby enabling to restrain the COD during high-output operation, the resonator end surface deterioration, and the like, so that it is possible to realize a nitride semiconductor laser device having high output and long lifetime.

Note that, for the nitride semiconductor laser device according to the third embodiment, an ion specie implanted to form the ion implanted part 304 is described as Al, but the ion specie may be another ion specie, such as H, B, C, N, Si, Zn, Ga, As, or In. Note also that the amount of implanted ion specie is desirably from 1×10⁴ cm⁻² to 1×10¹⁶ cm⁻².

For example, when ion specie such as H, B, C, N, or Zn is implanted, the ion implanted part 304 becomes a high-resistant part in the active layer 105, the first cladding layer 103, and the second cladding layer 106, which makes it possible to expect not only the light transmission effect of making the end part not to absorb light emitted from the active layer 105 but also high-resistance effect, namely, an effect of forming the resonator end part as a current non-injected region, so that it is possible to expect higher output and longer lifetime of the laser device. On the other hand, when Si is implanted as the ion, the ion implanted part 304 becomes n-type, so that if all layers adjacent to the ion implanted part 304 are p-type, a p-n-p junction is formed, which makes it possible to expect the same effect as described above obtained by forming the resonator end part as the current non-injected region. Moreover, when III group ion specie such as B, Al, Ga, or In ion specie is implanted, it is possible to control to set a composition ratio of a III group element in the ion implanted part 304 to be greater than a composition ratio of a III group element in the active layer 105 by disordering, so that window structure tuning becomes possible. When a wavelength is tuned by implanting the III group ion specie, it is preferable to implant an ion specie of a large amount of 1×10¹⁶ cm⁻² or more. By implanting such a large amount of an ion specie, it is possible to change the composition ratio of the III group element in the ion implanted part 304.

Moreover, the ion specie implanted to form the ion implanted part 304 may be two or more ion species. For example, by implanting a III group element such as Al together with In, or by implanting a III group element such as Al together with Zn, it is possible to realize a window structure having better characteristics. More specifically, when Al and In are implanted at the same time, In has more mass and more diffusion coefficient in GaN compared to Al, so that In is suitable to disorder the active layer 105. However, In has an effect of reducing a bandgap of the active layer 105. Therefore, In is implanted together with Al having the same amount as the In, so that it is possible to compensate the effect of In and to increase the bandgap of the active layer 105. In other words, it is possible to form the ion implanted part 304 which does not absorb light. On the other hand, when Al and Zn are implanted at the same time, it is possible to expect a bandgap increase effect from Al and a high resistance effect from Zn, so that it is possible to realize a window structure having both of the light transmisison effect and the high resistance effect.

Furthermore, according to the nitride semiconductor laser device of the third embodiment, the window structure is formed by applying ion implantation to a semiconductor layer. Therefore, since there is almost no difference between refractive index of the ion implanted part 304 and refractive index of the ion non-implanted part, an light confinement structure including the active layer 105, the stripe-shaped waveguide, and the current blocking layer 301 in the laser device is almost similar to an light confinement structure including the ion implanted part 304 at the resonator end part, so that it is possible to realize reliable laser oscillation.

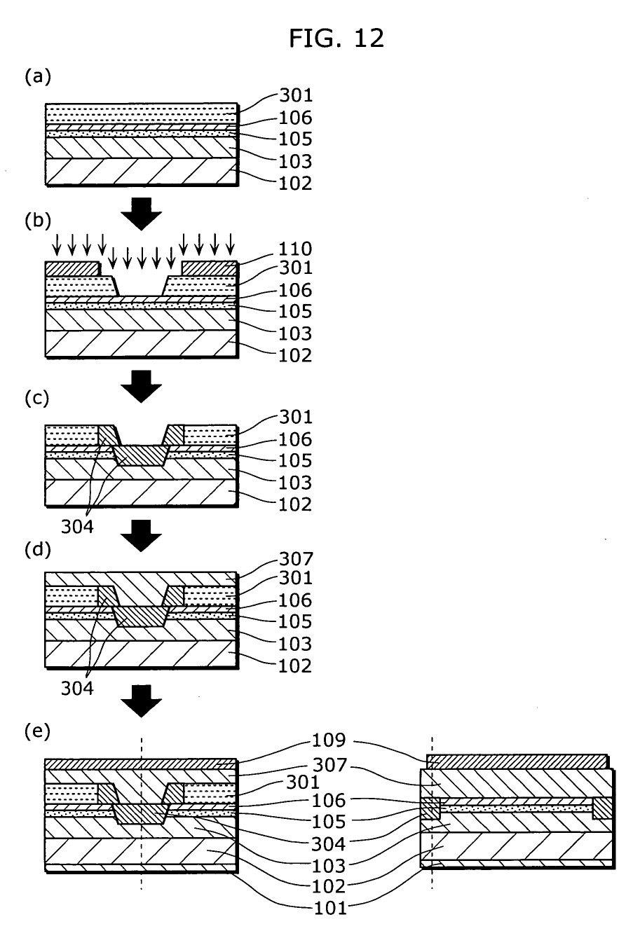

In order to manufacture the nitride semiconductor laser device having the structure as shown in FIGS. 10 and 11, a manufacturing method shown in FIG. 12, for example, is conceived. FIG. 12 shows cross-sectional views for explaining the method of manufacturing the nitride semiconductor laser device according to the third embodiment of the present invention. In FIG. 12, the same components are designated by the same reference numerals in FIGS. 10 and 11, and the structures of those components are the same as described above.

Firstly, for example, on a (0001) plane the n-type GaN substrate 102 having a dislocation density in a range of 10⁶ cm⁻³, using the crystal growth method such as the MOCVD method, sequentially are stacked: the n-type GaN buffer layer (not shown); the first cladding layer 103 made of n-type GaN or n-type AlGaN; the InGaN multiple quantum well active layer 105; the second cladding layer 106 made of p-type or undoped GaN, or p-type or undoped AlGaN; and the current blocking layer 301 made of n-type or undoped AlGaN (FIG. 12(a)). The active layer 105 emits blue-violet light having a wavelength of 405 nm by current injection.

Next, on the current blocking layer 301, a photoresist (not shown) having a stripe-shaped opening is formed. Using the photoresist as a mask, in the current blocking layer 301, a stripe-shaped opening is formed by performing, for example, the ICP dry etching using CI₂ gas.

Next, on the current blocking layer 301, a SiO₂ mask 110 having an opening formed only at the resonator end part is formed. Then, in the current blocking layer 301 and the second cladding layer 106 is applied with ion implantation at an accelerating voltage using, for example, Al ion. Thereby the voltage makes the ion reach the active layer 105 and a part of the first cladding layer 103. As a result, the ion implanted part 304 can be formed at a part which is to be the resonator end part in the first cladding layer 103 and the active layer 105. An amount of the implanted ion is 1×10¹⁵ cm⁻², for example. After that, the ion implanted part 304 is applied with heat treatment having a temperature of 800°0 C. or higher, for example thermal annealing having a temperature of 1000° C. or higher, so that damage on the ion implanted part 304 is restored and the active layer 105 at the resonator end part is disordered by diffusing the implanted ion in the ion implanted part 304 (FIGS. 12(b) and (c)).

Next, from the opening in the current blocking layer 301, the third cladding layer 307 made of p-type AlGaN is re-grown using the crystal growth method such as the MOCVD method. After that, the second cladding layer 106 (in a case of p-type) and the third cladding layer 307 are applied with thermal annealing in the N₂ atmosphere, for example with 750° C. and 30 minutes, in order to activate p-type impurity in the second cladding layer 106 (in a case of p-type) and the third cladding layer 307 (FIG. 12(d)).

Next, after activating the p-type impurity, on the third cladding layer 307, a Ni/Pt/Au electrode is formed using, for example, EB evaporation and liftoff. Here, in order to reduce contact resistance regarding the p-type layer, sintering of 600° C. in the N₂ atmosphere is performed to form an ohmic electrode (p-electrode 109).

Next, the n-type GaN substrate 102 is polished up to a thickness of about 150 μm from the rear surface. Then, on the rear surface of the n-type GaN substrate 102, a Ti/Al/Ni/Au electrode is formed using, for example, the EB evaporation and liftoff. Here, in order to reduce contact resistance regarding the n-type layer, sintering of 600° C. in the N₂ atmosphere is performed to form an ohmic electrode (n-electrode 101). Thus, the nitride semiconductor laser device having the structure as shown in FIGS. 10 and 11 is formed (FIG. 12(e)).

As described above, according to the method of manufacturing the nitride semiconductor laser device of the third embodiment, the p-type layer (third cladding layer 307) is formed by the re-growth, after forming the window structure using the ion implantation and the thermal annealing. Therefore, without exposing the p-type layer (third cladding layer 307) to a high temperature of 800°0 C. or higher, the nitride semiconductor laser device having the window structure can be manufactured, so that it is possible to realize a nitride semiconductor laser device having high output and long lifetime.

Note that, in the above method of manufacturing the nitride semiconductor laser device, Al is used as an example of the ion specie implanted to form the ion implanted part 304, however, the ion specie may be another ion specie such as H, B, C, N, Si, Zn, Ga, As, or In. Furthermore, a plurality of ion species may be implanted at the same time. The amount of implanted ion specie is desirably within a range from 1×10¹⁴ cm⁻² to 1×10¹⁶ cm⁻², and when III group ion specie such as Al, Ga, or In is implanted, the amount is preferably 1×10¹⁶ cm⁻² or more.

Note also that, during the ion implantation shown in FIGS. 12 (b) and (c), the n-type GaN substrate 102 and the semiconductor layer may be heated to have a temperature of 400° C. or higher. Thereby lattice energy of the n-type GaN substrate 102 becomes high thereby reducing crystalline damage during the ion implantation, so that it is possible to improve light transmission characteristics of the window structure.

Here, during the ion implantation, laser may be irradiated on the part where the ion implanted part 304 is to be formed. Note that the laser has energy greater than a bandgap of the part where the ion implanted part 304 is to be formed. Examples of such laser are a KrF laser (wavelength 248 nm), the third harmonic of pulsed YAG laser having a wave (wavelength 355 nm), and the like. Thereby it is possible to selectively heat only the part where the ion implanted part 304 is to be formed, thereby reducing the crystalline damage during the ion implantation, so that it is possible to improve the light transmission characteristics of the window structure.

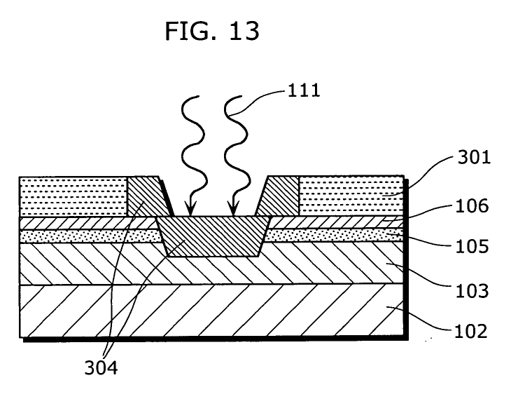

Note also that, during the heat treatment after the ion implantation shown in FIGS. 12 (b) and (c), the ion implanted part 304 may be irradiated by laser 111, such as the KrF laser (wavelength 248 nm) or the third harmonic of pulsed YAG laser having a wave (wavelength 355 nm), as shown in FIG. 13, in order to heat the part where the ion implanted part 304 is to be formed to have a temperature of 800° C. or higher. Thereby it is possible to selectively heat only the part where the ion implanted part 304 is to be formed.

### Fourth Embodiment

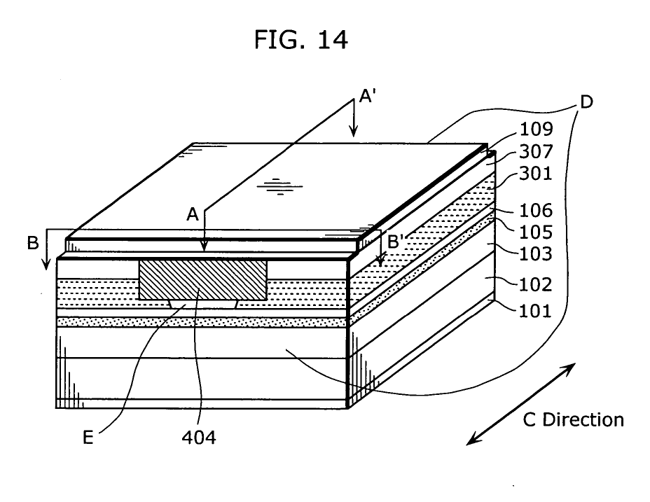

The following describes in detail a nitride semiconductor laser device and a manufacturing method thereof according to the fourth embodiment with reference to FIGS. 14 to 16. The fourth embodiment describes a nitride semiconductor laser device having an embedded-stripe-shaped waveguide and a high-resistivity current-non-injected region formed using ion implantation.

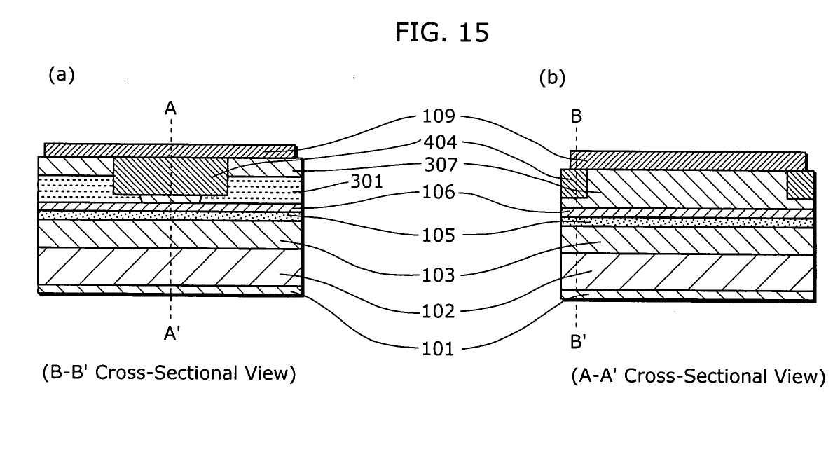

FIG. 14 is a perspective view of the nitride semiconductor laser according to the fourth embodiment. FIG. 15(a) is a cross-sectional view of the nitride semiconductor laser device from the resonance direction of the resonator (C direction of FIG. 14), taken along line B-B′ of FIG. 14. FIG. 15(b) is a cross-sectional view of the nitride semiconductor laser device from a direction from a direction perpendicular to the resonance direction of the resonator, taken along line A-A′ of FIG. 14. In FIGS. 14 and 15, the same components are designated by the same reference numerals in FIGS. 10 and 11, and the structures of those components are the same as described above.

The semiconductor laser device according to the fourth embodiment includes: the n-electrode 101; the n-type GaN substrate 102; the first cladding layer 103; an ion implanted part 404; the active layer 105; the second cladding layer 106; the third cladding layer 307; and the current blocking layer 301; and the p-electrode 109. Note that the ion implanted part 404 is one example of a transformed part according to the present invention.

Here, the first cladding layer 103, the active layer 105, the second cladding layer 106, the third cladding layer 307, and the current blocking layer 301 form a resonator which causes laser oscillation.

The semiconductor laser device according to the fourth embodiment is a blue-violet semiconductor laser device made of a nitride semiconductor having an embedded-stripe-shaped waveguide. The semiconductor laser device has a high resistivity and current non-injected region (ion implanted part 404) formed at a region (resonator end part) positioned closely to a resonator end surface D, by applying ion implantation to the third cladding layer 307 and a part or all of the current blocking layer 301. That is, the nitride semiconductor laser device according to the fourth embodiment is a blue-violet semiconductor laser device in which a high-resistivity and current non-injected region (ion implanted part 404) is formed by transforming a semiconductor layer positioned above the active layer 105 in the resonator end parts which sandwich the middle part of the resonator where light is resonated.

For example, on the n-type GaN substrate 102 are sequentially stacked; the first cladding layer 103 which is made of n-type AlₓGa₁₋ₓN (where 0≦x≦1); the InGaN multiple quantum well active layer 105 which is made of an In_{1-xb}Ga_{xb}N (where 0≦xb≦1) barrier layer and an In_{1-xw}Ga_{xw}N (where 0≦xw≦1) well layer; the second cladding layer 106 made of p-type or undoped GaN, or p-type or undoped AlₓGa₁₋ₓN; the current blocking layer 301 made of n-type or undoped AlᵥGa₁₋ᵥN (where 0≦xv≦1); and the third cladding layer 307 made of p-type AlₓGa₁₋ₓN. The current blocking layer 301 has a stripe-shaped opening (E in FIG. 12). On a top surface of the third cladding layer 307, an ohmic electrode made of Ni/Pt/Au is formed as the p-electrode 109. On a rear surface of the n-type GaN substrate 102, an ohmic electrode made of Ti/Al/Ni/Au is formed as the n-electrode 101. The ion implanted part 404 is formed in the third cladding layer 307 inside the opening of the current blocking layer 301.

Furthermore, regarding the resonator end part, the ion implanted part 404 is formed at the third cladding layer 307 and a part or all of the current blocking layer 301. The first cladding layer 103 and the current blocking layer 301 (in a case of n-type) as n-type layers are doped with Si as impurity, and on the other hand, the second cladding layer 106 (in a case of p-type) and the third cladding layer 307 as p-type layers are doped with Mg as impurity. The ion implanted part 404 is implanted with Zn by an impurity concentration of 1×10¹⁵ cm⁻². Furthermore, in the ion implanted part 404, using ion implantation, resistance of the third cladding layer 307 is increased in order to have specific resistance of 10⁸ Ωcm or more for example, so that the ion implanted part 404 has a function as a current injection blocking layer for blocking current injected in the resonator end part.

As described above, according to the nitride semiconductor laser device of the fourth embodiment, the ion implanted part 404 has a function as a current injection blocking layer for blocking current injected in the resonator end part. As a result, heating is restrained at the resonator end part, thereby enabling to restrain the COD during high-output operation, the resonator end surface deterioration, and the like, so that it is possible to realize a laser device having high output and long lifetime.

Furthermore, according to the nitride semiconductor laser device of the fourth embodiment, the current non-injected region is formed by applying ion implantation to a semiconductor layer. Therefore, since there is almost no difference between refractive index of the ion implanted part 404 and refractive index of the ion non-implanted part, the current non-injected region can be formed without changing a structure of the waveguide at the resonator end part, so that it is possible to realize a reliable single horizontal mode operation.

Note that, for the nitride semiconductor laser device according to the fourth embodiment, an ion specie implanted to form the ion implanted part 404 is described as Zn, but as far as the resistance of third cladding layer 307 can be increased by the ion implantation, the ion specie may be another ion specie, such as H, B, C, N, Al, Si, Ga, As, or In. In the nitride semiconductor laser device according to the fourth embodiment, thermal annealing with a high temperature of higher than 800° C. ) is not performed after the ion implantation, so that the ion specie is not limited to Zn as far as the resistance is not reduced due to heat treatment with a relatively low temperature of 600° C. or less in other processing. For example, when Si is implanted as the ion specie, the ion implanted part 404 becomes n-type, so that since all layers adjacent to the ion implanted part 404 are p-type, a p-n-p junction is formed, which makes it possible to expect the same effect as described above obtained by forming the resonator end part as the current non-injected region. The amount of implanted ion specie is desirably within a range from 1×10¹⁴ cm⁻² to 1×10¹⁶ cm⁻². Moreover, the ion specie implanted to the ion implanted part 404 may be two or more ion species.

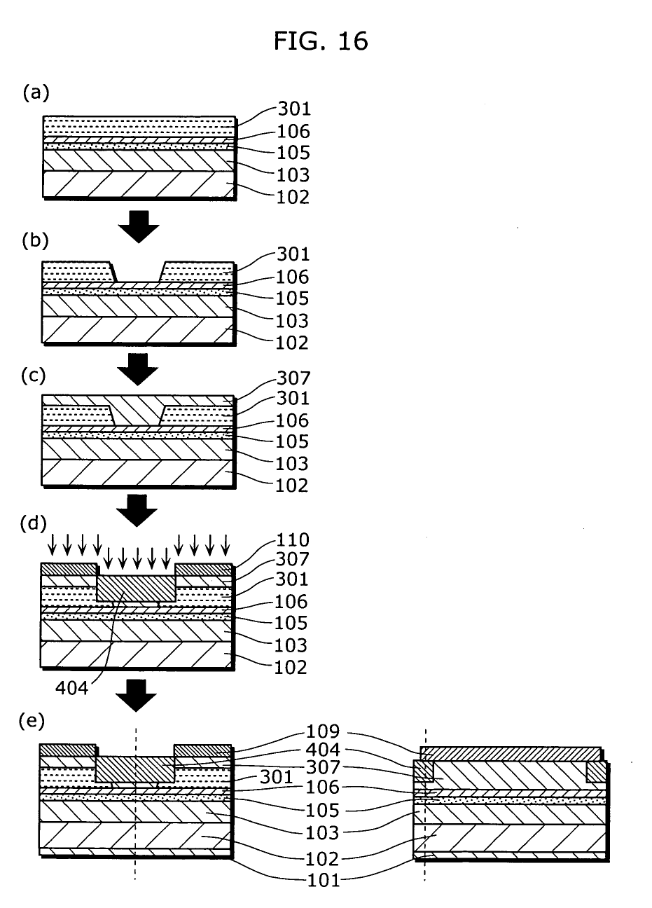

In order to manufacture the nitride semiconductor laser device having the structure as shown in FIGS. 14 and 15, a manufacturing method shown in FIG. 16, for example, is conceived. FIG. 16 shows cross-sectional views for explaining the method of manufacturing the nitride semiconductor laser device according to the fourth embodiment of the present invention. In FIG. 16, the same components are designated by the same reference numerals in FIGS. 14 and 15, and the structures of those components are the same as described above.

Firstly, for example, on a (0001) plane the n-type GaN substrate 102 having a dislocation density in a range of 10⁶ cm⁻³, using the crystal growth method such as the MOCVD method, sequentially are stacked: the n-type GaN buffer layer (not shown); the first cladding layer 103 made of n-type GaN or n-type AlGaN; the InGaN multiple quantum well active layer 105; the second cladding layer 106 made of p-type or undoped GaN, or p-type or undoped AlGaN; and the current blocking layer 301 made of n-type or undoped AlGaN (FIG. 16(a)). The active layer 105 emits blue-violet light having a wavelength of 405 nm by current injection.

Next, on the current blocking layer 301, a photoresist (not shown) having a stripe-shaped opening is formed. Using the photoresist as a mask, the stripe-shaped opening is formed in the current blocking layer 301 by performing, for example, the ICP dry etching using CI₂ gas (FIG. 16(b)).

Next, the third cladding layer 307 made of p-type AlGaN is re-grown from the opening in the current blocking layer 301 using the crystal growth method such as the MOCVD method. After that, the second cladding layer 106 (in a case of p-type) and the third cladding layer 307 are applied with thermal annealing in the N₂ atmosphere, for example with 750° C. and 30 minutes, in order to activate p-type impurity in the second cladding layer 106 (in a case of p-type) and the third cladding layer 307 (FIG. 16(c)).

Next, after activating the p-type impurity, on the third cladding layer 307, a SiO₂ mask 110 which has an opening only at a lo part which is to be the resonator end part is formed. Then, the third cladding layer 307 is applied with ion implantation at an accelerating voltage using, for example, Zn ion. Thereby the voltage makes the ion reach the third cladding layer 307 and a part or all of the current blocking layer 301. As a result, the ion implanted part 404 can be formed at a part which is to be the resonator end part in the third cladding layer 307 and the current blocking layer 301 (FIG. 16(d)). An amount of the implanted ion is 1×10¹⁵ cm⁻², for example.

Next, on the third cladding layer 307, a Ni/Pt/Au electrode is formed using, for example, the EB evaporation and liftoff. Here, in order to reduce contact resistance regarding the p-type layer, sintering of 600° C. in the N₂ atmosphere is performed to form an ohmic electrode (p-electrode 109).

Next, the n-type GaN substrate 102 is polished up to a thickness of about 150 μm from the rear surface. Then, on the rear surface of the n-type GaN substrate 102, a Ti/Al/Ni/Au electrode is formed using, for example, the EB evaporation and liftoff. Here, in order to reduce contact resistance regarding the n-type layer, sintering of 600° C. in the N₂ atmosphere is performed to form an ohmic electrode (n-electrode 101). Thus, the nitride semiconductor laser device having the structure as shown in FIGS. 14 and 15 is formed (FIG. 16(e)).

As described above, according to the method of manufacturing the nitride semiconductor laser device of the fourth embodiment, the high-resistivity and current non-injected region is formed using the ion implantation which does not reach the active layer 105. Therefore, without performing thermal annealing of a high temperature in order to restore damage resulted from ion implantation, it is possible to manufacture the nitride semiconductor laser device having the structure with the current non-injected region at the resonator end part, so that it is possible to realize a blue-violet nitride semiconductor laser device having high output and long lifetime.

Note that, in the above method of manufacturing the nitride semiconductor laser device, Zn is used as an example of the ion specie implanted to form the ion implanted part 404, however, the ion specie may be another ion specie such as H, B, C, N, Al, Si, Ga, As, or In. The amount of implanted ion specie is desirably within a range from 1×10¹⁴ cm⁻² to 1×10¹⁶ cm⁻².

Note also that, during the ion implantation shown in FIG. 16(d), the n-type GaN substrate 102 and the semiconductor layer may be heated to have a temperature of 400° C. or higher. Thereby lattice energy of the n-type GaN substrate 102 becomes, so that it is possible to reduce crystalline damage during the ion implantation.

Here, during the ion implantation, it is possible to irradiate laser on the part where the ion implanted part 404 is to be formed. Note that the laser has energy greater than a bandgap of the part where the ion implanted part 404 is to be formed. Examples of such laser are a KrF laser (wavelength 248 nm), the third harmonic of pulsed YAG laser having a wave (wavelength 355 nm), and the like. Thereby it is possible to selectively heat only the part where the ion implanted part 404 is to be formed, thereby reducing the crystalline damage during the ion implantation, so that it is possible to reduce the crystalline damage during the ion implantation.

Although only some exemplary embodiments of the present invention have been described in detail above, those skilled in the art will be readily appreciate that many modifications are possible in the exemplary embodiments without materially departing from the novel teachings and advantages of the present invention. Accordingly, all such modifications are intended to be included within the scope of this invention.

For example, the above embodiments have describes the blue-violet laser device which emits light having a wavelength of 405 nm, but, by forming the active layer as a multiple quantum well which has: a barrier layer made of Al_{xb}Ga_{yb}In_{(1-xb-yb)}N (where 0≦xb≦1, 0≦yb≦1, 0≦1-xb-yb≦1); and a well layer made of Al_{xw}Ga_{yw}In_{(1-xw-yw)}N (where 0≦xw≦1, 0≦yw≦1, 0≦1-xw-yw≦1), it is possible to form the window structure as described above for an ultraviolet laser device which emits light having a wavelength of 360 nm, which makes it possible to realize an ultraviolet laser device having high output and long lifetime.

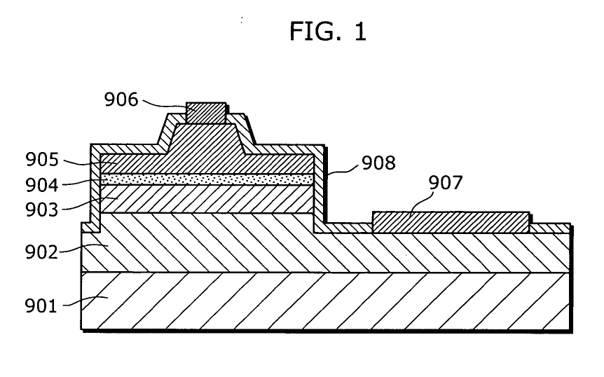

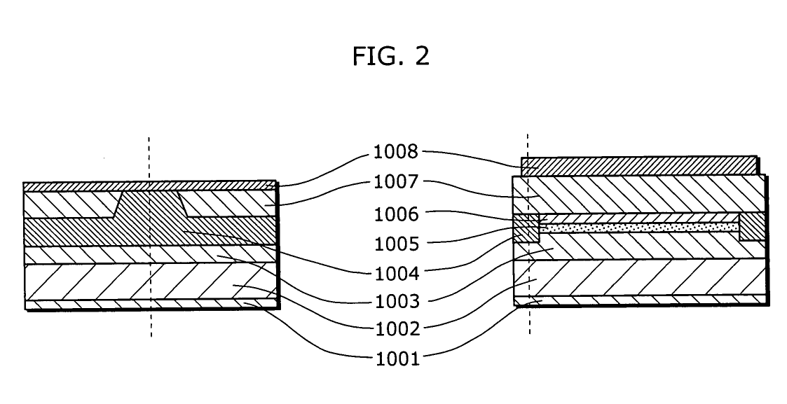

Moreover, all of the above embodiments have described that the nitride semiconductor laser has the n-type GaN substrate and on a rear surface of the substrate the n-electrode is formed. However, the substrate may be an insulating substrate, such as a sapphire substrate, and the n-electrode as shown in the conventional example of FIG. 1 is formed on a front surface of such a substrate. Furthermore, the substrate may be a conducting substrate or an insulating substrate. Still further, the substrate may be a substrate made of GaN, sapphire, SiC, ZnO, Si, GaAs, InP, LiGaO₂, or LiAlO₂, or may also be a mixed crystal substrate made of those crystals. Still further, the substrate may have any plane directions, and may have an off-angle from a representative plane. Still further, in the substrate, it is desirable that the part where the stripe-shaped waveguide is formed has dislocation density in a range of 10⁶ cm⁻² or less. Still further, the semiconductor layer formed on the substrate may have a multilayer structure as far as desired laser characteristics can be realized. Still further, the crystal growth method used to form a semiconductor layer on the substrate may be not only the MOCVD method, but also a molecular beam epitaxy (MBE) method or a hydride vapor phase epitaxy (HVPE) method.

### INDUSTRIAL APPLICABILITY

The nitride semiconductor laser device according to the present invention is suitable as a blue semiconductor laser device having high output and long lifetime which can be used for a light source for writing and reading a high-density optical disk, such as a next generation DVD (Blu-ray Disc).

What is claimed is:

1. A nitride semiconductor laser device which is made of a nitride semiconductor, said nitride semiconductor laser device comprising a resonator which causes laser oscillation,
wherein said resonator has an transformed part at an end part of said resonator in a resonance direction.

2. The nitride semiconductor laser device according to claim 1,
wherein said resonator has: an n-type cladding layer; an active layer positioned above said n-type cladding layer; and a p-type cladding layer positioned above said active layer, and
said transformed part is positioned in said p-type cladding layer.

3. The nitride semiconductor laser device according to claim 2,
wherein said transformed part is a part in said p-type cladding layer, the part having resistance that is increased more than other part in said p-type cladding layer.

4. The nitride semiconductor laser device according to claim 3,
wherein said resonator has a current blocking layer which is positioned above said active layer and which has a stripe-shaped opening, and
said transformed part is in said opening.

5. The nitride semiconductor laser device according to claim 1,
wherein said resonator has: an n-type cladding layer; an active layer positioned above said n-type cladding layer; and a p-type cladding layer positioned above said active layer, and
said transformed part is positioned in said active layer.

6. The nitride semiconductor laser device according to claim 5,
wherein said transformed part is a part in said active layer, the part being disordered.

7. The nitride semiconductor laser device according to claim 6,
wherein said transformed part is a part in said active layer, the part having bandgap energy that is increased more than bandgap energy of other part in said active layer.

8. The nitride semiconductor laser device according to claim 7,
wherein said active layer is made of aluminum-gallium-indium-nitride (AlGaInN), and
said transformed part is a part where one of ion species of boron (B), aluminium (Al), and gallium (Ga) is implanted and where a composition ratio of the one of ion species of boron (B), aluminium (Al), and gallium (Ga) in said active layer is greater than an average composition ratio of the one of ion species of boron (B), aluminium (Al), and gallium (Ga) in said active layer.

9. The nitride semiconductor laser device according to claim 8,
wherein said transformed part is a part where ion species including In and one of boron (B), aluminium (Al), and gallium (Ga) are implanted.

10. The nitride semiconductor laser device according to claim 1,
wherein said transformed part is a part where at least one ion specie of hydrogen (H), boron (B), carbon (C), nitrogen (N), aluminium (Al), silicon (Si), zinc (Zn), gallium (Ga), arsenic (As), and Indium (In) is implanted.

11. A method of manufacturing a nitride semiconductor laser device which is made of a nitride semiconductor device, the nitride semiconductor laser having a resonator which causes laser oscillation, said method comprising:
forming, on a substrate, a semiconductor layer which is made of the nitride semiconductor; and
forming a transformed part by transforming a part in the semiconductor layer, the part being to be an end part of the resonator in a resonance direction.

12. The method of manufacturing the semiconductor layer according to claim 11,
wherein in said forming of the semiconductor layer, an n-type cladding layer and an active layer are sequentially formed on the substrate by a crystal growth method, and
in said forming of the transformed part, the transformed part is formed at a part in the active layer, the part being to be an end part of the resonator in a resonance direction,
said method further comprising:
heating the transformed part to be disordered;
forming a p-type cladding layer by the crystal growth method above the active layer in which the disordered transformed part is formed; and
forming a stripe-shaped ridge part in the p-type cladding layer.

13. The method of manufacturing the semiconductor layer according to claim 12,
wherein in said heating, the transformed part is heated to have a temperature that is equal to or higher than 800°0 C.

14. The method of manufacturing the semiconductor layer according to claim 13,
wherein in said heating, the transformed part is heated by irradiating a laser beam.

15. The method of manufacturing the semiconductor layer according to claim 11,
wherein in said forming of the semiconductor layer, an n-type cladding layer, an active layer, and a p-type cladding layer are sequentially formed on the substrate by a crystal growth method, and
in said forming of the transformed part, the transformed part is formed at a part in the p-type cladding layer, the part being to be an end part of the resonator in a resonance direction,
said method further comprising
forming a stripe-shaped ridge part in the p-type cladding layer so that the transformed part is formed as the ridge part.

16. The method of manufacturing the semiconductor layer according to claim 15, further comprising
activating a p-type impurity in the p-type cladding layer, and
wherein in said forming of the transformed part, the transformed part is formed in the p-type cladding layer where said activating of the p-type impurity is performed.

17. The method of manufacturing the semiconductor layer according to claim 11,
wherein in said forming of the semiconductor layer, an n-type cladding layer, an active layer, and a blocking layer are sequentially formed on the substrate by a crystal growth method, and then a stripe-shaped opening is formed in the blocking layer, and
in said forming of the transformed part, the transformed part is formed at a part in the active layer, the part being to be an end part of the resonator in a resonance direction, and
said method further comprising:
heating the transformed part to be disordered; and
forming, after said heating, a p-type cladding layer by growing the p-type cladding layer from the opening by the crystal growth method.

18. The method of manufacturing the semiconductor layer according to claim 17,
wherein in said heating, the transformed part is heated to have a temperature that is equal to or higher than 800°0 C..

19. The method of manufacturing the semiconductor layer according to claim 18,
wherein in said heating, the transformed part is heated by irradiating a laser beam.

20. The method of manufacturing the semiconductor layer according to claim 11,
wherein in said forming of the semiconductor layer, an n-type cladding layer, an active layer, and a blocking layer are sequentially formed on the substrate by a crystal growth method, then a stripe-shaped opening is formed in the blocking layer, and then the p-type cladding layer is grown from the opening by the crystal growth method, and
in said forming of the transformed part, the transformed part is formed at a part in the p-type cladding layer in the opening, the part being to be an end part of the resonator in a resonance direction.

21. The method of manufacturing the semiconductor layer according to claim 20, further comprising
activating a p-type impurity in the p-type cladding layer, and
wherein in said forming of the transformed part, the transformed part is formed in the p-type cladding layer where said activating of the p-type impurity is performed.

22. The method of manufacturing the semiconductor layer according to claim 11,
wherein in said forming of the transformed part, the transformed part is formed by applying ion implantation at a part where the transformed part is to be formed, during heating the substrate and the semiconductor layer to have a temperature that is equal to or higher than 400° C.

23. The method of manufacturing the semiconductor layer according to claim 22,
wherein in said forming of the transformed part, the ion implantation is performed during irradiating a laser beam at a part where the ion implantation is applied.
